(19) United States
(12) Patent Application Publication
(10) Pub. No.: US 2012/0113570 A1
(43) Pub. Date: May 10, 2012

(54) SERVER CABINET STRUCTURE WITH VIBRATION ISOLATION FUNCTION

(75) Inventors: Chun-Ying Yang, Taipei (TW); Ming-Hung Shih, Taipei (TW); Yen-Cheng Lin, Taipei (TW); Kao-Ling Chang, Taipei (TW)

(73) Assignee: INVENTEC CORPORATION, Taipei (TW)

(21) Appl. No.: 13/158,659

(22) Filed: Jun. 13, 2011

(30) Foreign Application Priority Data
Nov. 5, 2010 (TW) 099138228

(51) Int. Cl. H05K 7/02

(52) U.S. Cl. 361/679.01

(57) ABSTRACT

A server cabinet structure with a vibration isolation function includes a rack, a accommodated frame, and an isolator. The accommodated frame is installed on the rack, and is disposed in an accommodation room defined the rack. The isolator is installed in the accommodated frame, and is partially exposed out of the rack. The isolator does not increase volume of the server cabinet additionally, and is suitable for being applied to application environment which has narrow spaces.

### CROSS-REFERENCE TO RELATED APPLICATIONS

This non-provisional application claims priority under 35 U.S.C. §119(a) on Patent Application No(s). 099138228 filed in Taiwan, R.O.C. on Nov. 5, 2010, the entire contents of which are hereby incorporated by reference.

### BACKGROUND OF THE INVENTION

1. Field of the Invention

The present invention relates to a server cabinet, and more particularly to a server cabinet structure with a vibration isolation function.

2. Related Art

With the development of science and technology, a computer device is expected to open and run various programs within a shortest period, so as to meet speed requirements of data processing from customers. Development objects of increasing processing speed and performing multiplex operation are achieved by increasing chip precision in the industry, so that server architecture consisting of many circuit boards and electronic components thereof is developed, and many server architecture further forms a data center.

When several main boards are installed in an existing server cabinet, the several main boards are placed on provided trays. Additionally, the server cabinet is divided into many rooms, so that all of the trays loaded with the main boards are arranged in the rack at intervals. In addition, multple sets of slide rail structures inside the cabinet are used to providing the trays for being inserted in the cabinet.

Most of conventional large server cabinets are not designed with a vibration isolation/shock absorption structure. If one main board in a server cabinet is required to be drawn out for replacement or repairing, an operator has to push the whole server cabinet from the system. Moreover, a room for operation is small, and the cabinet is large and heavy, so that during carrying and moving, a risk of damage to main boards in the server cabinet caused by shaking or external collision exists.

In order to solve the vibration isolation/shock absorption problem of a server cabinet, shock isolation/shock absorption devices are added to a server cabinet, for example, vibration isolation parts such as rubber pads, dampers, and springs, so as to enhance vibration isolation effectiveness and structural strength of the server cabinet. The conventional vibration isolation/shock absorption devices are selectively installed on the top or under the bottom of the server cabinet according to actual requirements, all of the which however are installed outside the server cabinet, so that the conventional vibration isolation/shock absorption devices can press against internal walls of a container room, thus providing the server cabinet with an effect of vibration isolation/shock absorption.

However, a vibration isolation/shock absorption structure in which a vibration isolation/shock absorption device is installed outside a server cabinet makes overall volume of the server cabinet even larger, which limits the number of server cabinets being able to be installed in a single container room, and the maximum number of the installation cannot be achieved, so that overall operation performance of a data center cannot be improved, and more container rooms have to be provided to install a preset number of the server cabinets successfully.

### SUMMARY OF THE INVENTION

In view of the above problems, the present invention is a server cabinet structure with a vibration isolation function, so as to solve the problem in which quantity of server cabinets installed in a container room cannot reach the maximum number because conventional vibration isolation/shock absorption devices of server cabinets are installed outside the cabinets, which causes spaces occupied by the server cabinets to be too large.

The server cabinet structure with the vibration isolation function of the present invention comprises a rack, an accommodated frame, and a first isolator. The rack has an accommodation room inside. The accommodated frame is installed on the rack, and the accommodated frame is disposed in the accommodation room defined by the rack. The first isolator is installed in the accommodated frame, and is partially exposed out of the rack.

The server cabinet structure with the vibration isolation function may further comprise at least one second isolator. The first isolator is installed at a top part of the rack, and the second isolator is installed at a bottom part of the rack.

Beneficial effects of the present invention are as follows. The isolators are installed in the rack and disposed in the rack, which does not increase the volume of the server cabinet additionally, and is suitable for being applied to application environment which has narrow spaces. So that the room can be installed with the maximum number of the server cabinets, thus achieving the highest operation performance.

### BRIEF DESCRIPTION OF THE DRAWINGS

The present invention will become more fully understood from the detailed description given herein below for illustration only, and thus are not limitative of the present invention, and wherein:

FIG. 1A is a schematic exploded view according to an embodiment of the present invention;

FIG. 1B is a schematic partially enlarged exploded view according to an embodiment of the present invention;

FIG. 1C is a schematic partially enlarged exploded view according to an embodiment of the present invention;

FIG. 2A is a schematic three-dimensional view according to an embodiment of the present invention;

FIG. 2B is a schematic three-dimensional partially enlarged view according to an embodiment of the present invention;

FIG. 2C is a schematic three-dimensional partially enlarged view according to an embodiment of the present invention;

FIG. 2D is a schematic three-dimensional partially enlarged view according to an embodiment of the present invention; and

FIG. 3 is schematic side view according to an embodiment of the present invention.

### DETAILED DESCRIPTION OF THE INVENTION

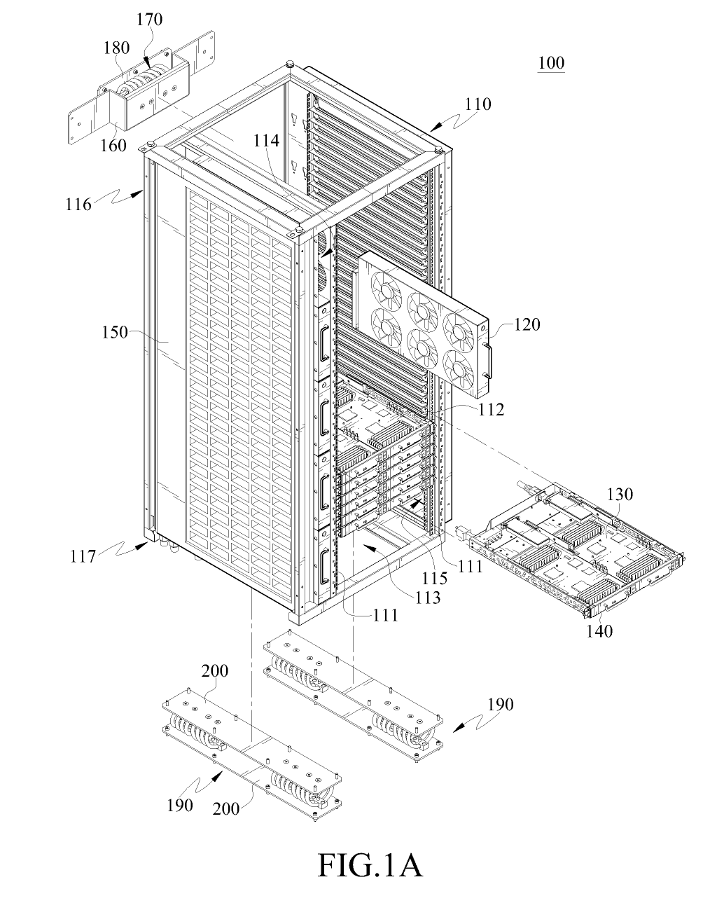

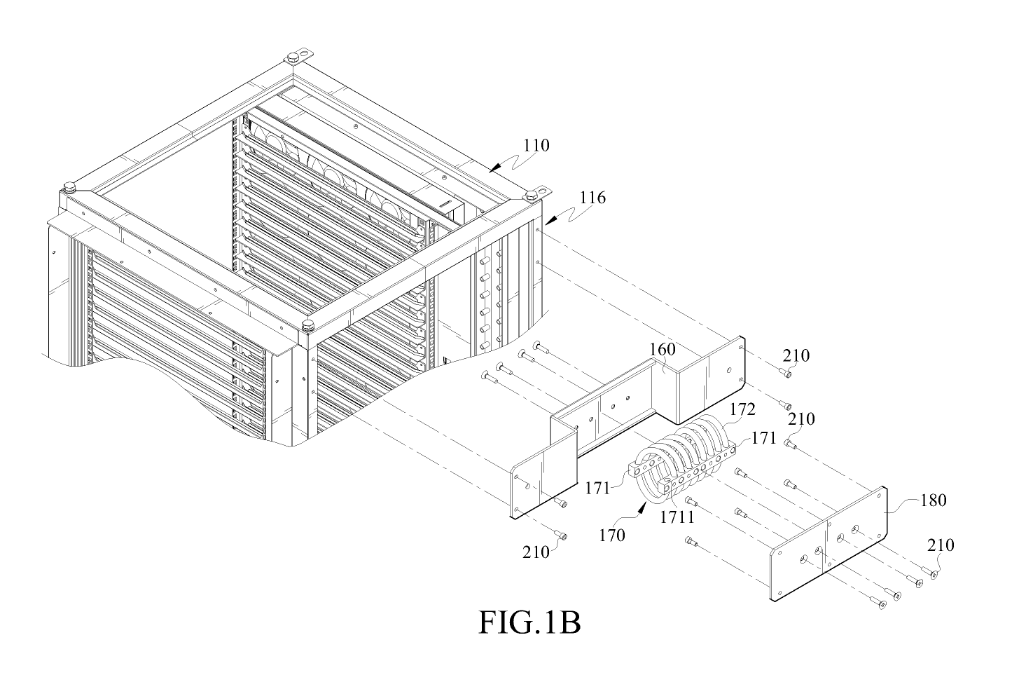

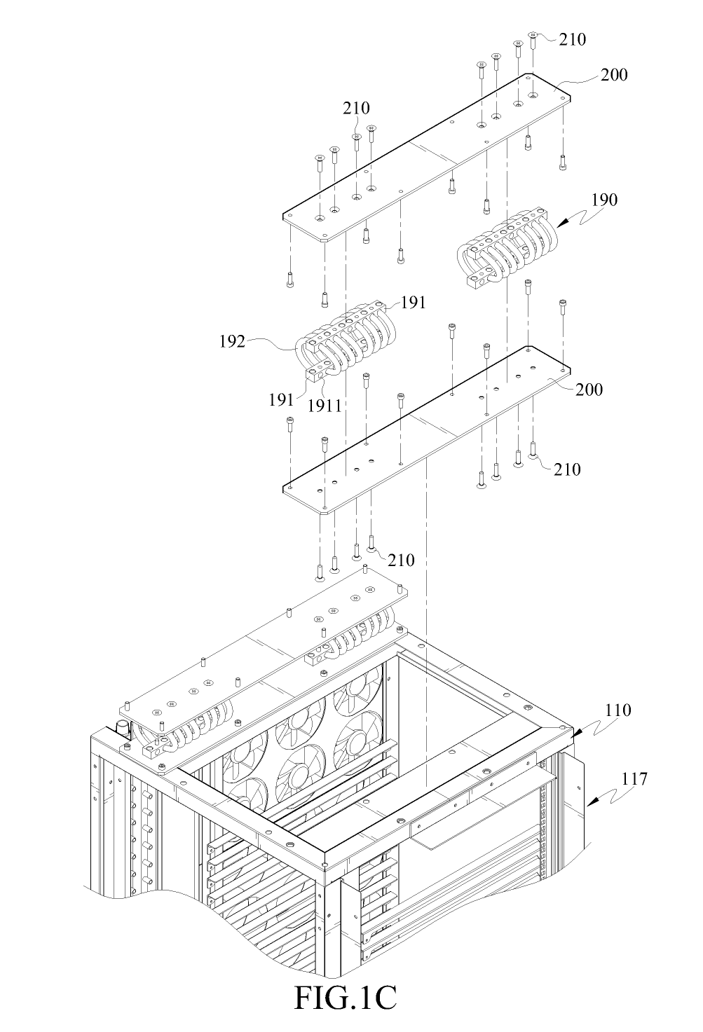

FIGS. 1A to 3 are schematic three-dimensional views and a schematic side view of an embodiment of the present invention, as shown in the figures, a server cabinet 100 of the present invention comprises a rack 110, at least one fan module 120, at least one circuit board 130, at least one tray 140, a radiator 150, an accommodated frame 160, and a first isolator 170.

The rack 110 is a hollow rack constituted by many steel bars, steel plates, and angle steel, so as to form an accommodation room inside the rack 110. Two side surfaces opposite to each other of the rack 110 respectively have two frame bars 111 opposite to each other and at least two guide rails 112. Moreover, the rack 110 is opened with an opening 113 on one side, and the opening 113 is in communication with the accommodation room, so that the inside of the rack 110 is in communication with the outside through the opening 113.

The guide rails 112 of the present invention are disposed on the frame bars 111 respectively, and protrude inwards from the frame bars 111 respectively. The guide rails 112 on the two frame bars 111 are arranged symmetrically. One of the side surfaces of the rack 110 further comprises at least one assembling frame 114. The assembling frame 114 is located in the accommodation room of the rack 110. One side surface of the rack 110 opposite to the assembling frame 114 is opened with a vent 115. The rack 110 has substantially a top part 116 and a bottom part 117, which are located at two ends of the rack 110 opposite to each other respectively.

The fan module 120 is laterally installed in the assembling frame 114 of the rack 110, so that the fan module 120 is held in the rack 110 and remains the installation position unchanged.

It should be noted that, the number of the guide rails 112 of the rack 110 is multiple, the multiple guide rails 112 on the frame bars 111 are disposed at intervals, and therefore an in-between accommodation room is formed between two adjacent guide rails 112. The height of the in-between accommodation room matches the height of the tray 140 exactly. Additionally, in the present invention, the number of the fan modules 120 and the number of the assembling frames 114 of the rack 110 are also multiple. The numbers of the components of the above server cabinet 100 are corresponding to each other, and those skilled in the art may adjust the numbers according to the practical requirements, which is not limited to the embodiments disclosed in the present invention.

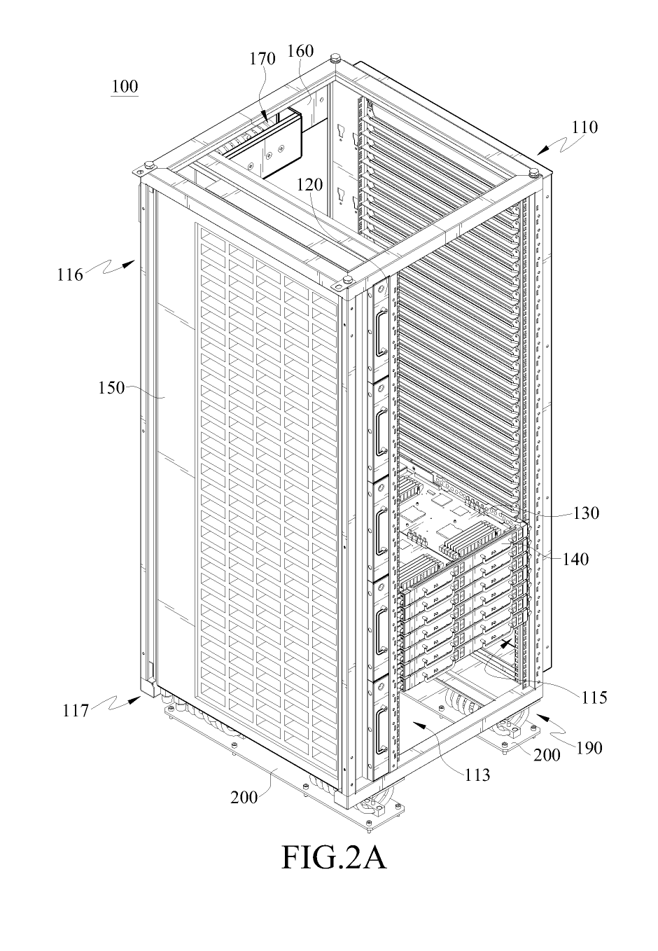

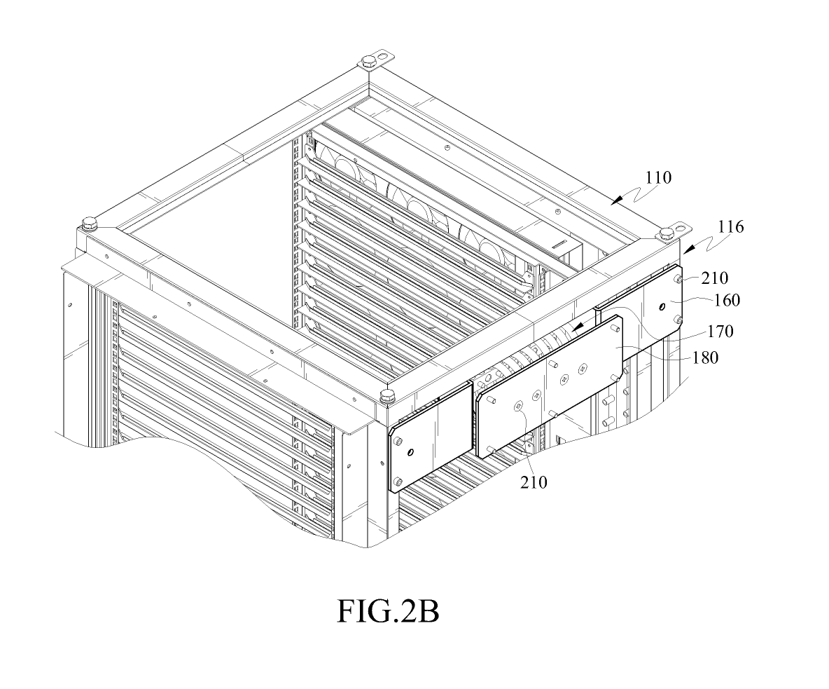

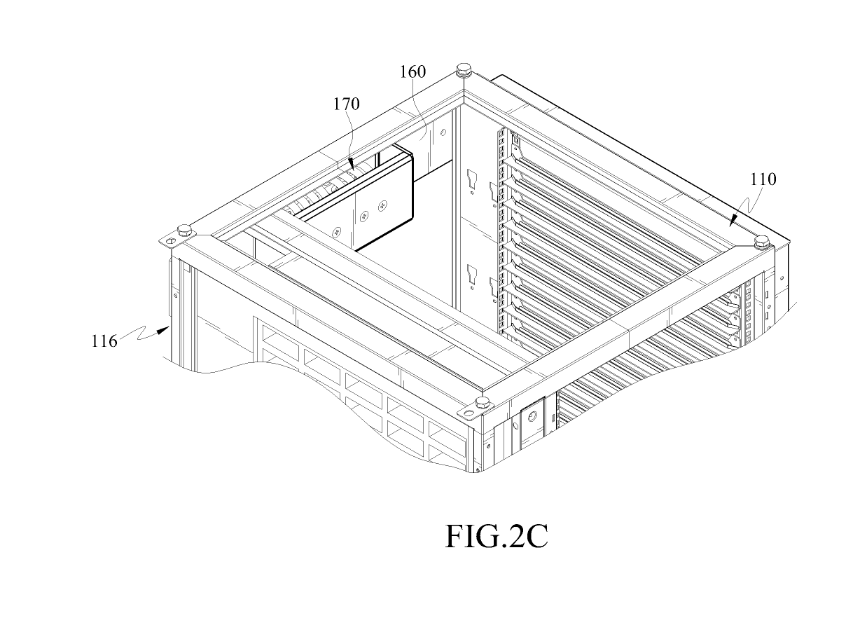

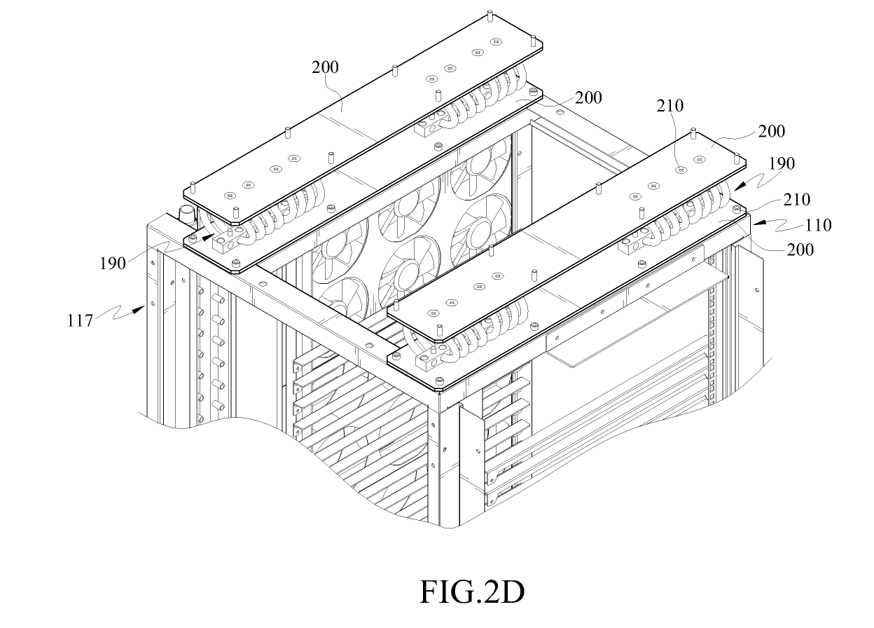

As shown in FIGS. 1A and 2A, the tray 140 of the present invention may be made of metal, and the circuit board 130 is placed on the tray 140. The circuit board 130 passes through the opening 113 from the lateral direction of the rack 110 along with the tray 140 to be installed on the two guide rails 112 and then slides in the accommodation room of the rack 110.

Referring to FIGS. 1A and 2A, the fan module 120 is electrically connected to an external power supply device to be actuated, and an airflow generated by the fan module 120 is blown to the rack 110. Therefore, the airflow of the fan module 120 passes through the tray 140 and is blown to the circuit board 130, and performs convention heat dissipation with the circuit board 130. Then, the airflow transversely passes through the circuit board 130 and is blown outside the rack 110 via the vent 115 of the rack 110.

The radiator 150 of the present invention is installed on the side surface of the rack 110 having the fan module 120, and is located outside the rack 110. The radiator 150 is connected to external cooling water (not shown), so that the cooling water is introduced into the rack 110 to assist heat dissipation, for improving the overall heat dissipation performance. The number of the radiators 150 of the present invention may be multiple, so as to provide the server cabinet 100 with an optimal heat dissipation effect.

As show in FIGS. 1A, 1B, and 2A to 2C, the accommodated frame 160 is of the shape of an housing frame, which forms a housing room recessed inwards formed by bending a plate. The accommodated frame 160 is fixedly disposed at the top part 116 of the rack 110, for example in a locked manner by using screws 210, or is installed on the rack 110 by welding. Those skilled in the art may select any suitable connection manner, and the present invention is not limited thereto.

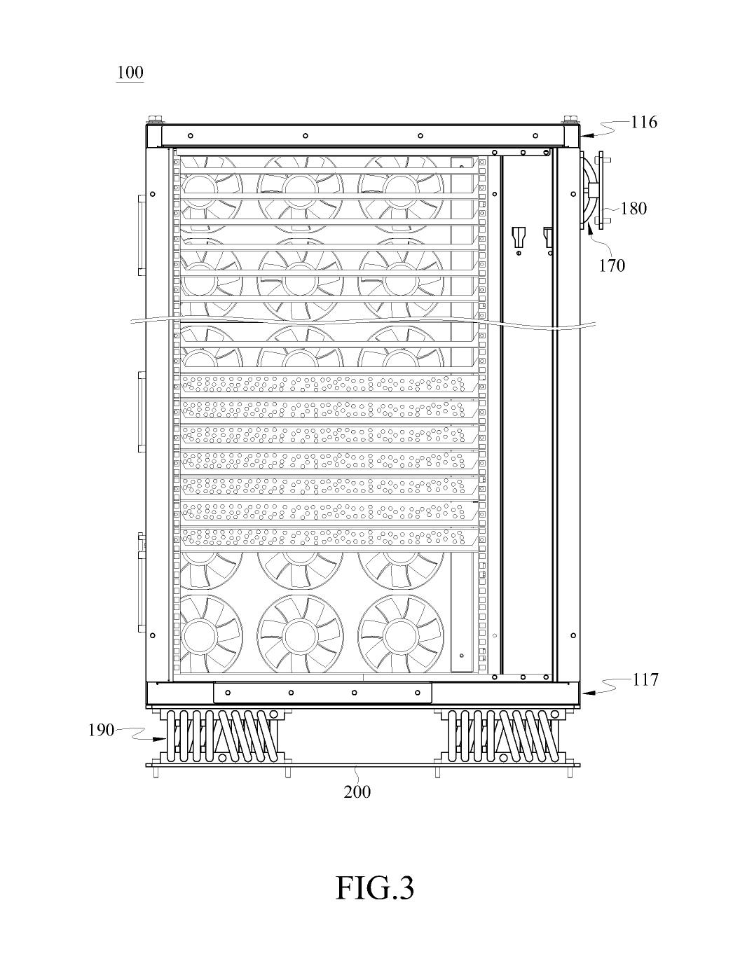

It should be noted that, the receiving frame 160 of the present invention is disposed in the accommodation room inside the rack 110, and does not exceed boundaries of the frame body of the rack 110. The first isolator 170 is installed in the accommodated frame 160, so that the first shock isolator 170 is located inside the rack 110. Only a small part of the first isolator 170 extends to the outside of the rack 110 (as shown in FIG. 3) for connecting to a wall of an outside machine room (or a container room), so as to provide the server cabinet 100 with the vibration isolation/shock absorption function.

Also referring to FIGS. 1A, 1B, and 2A to 2C, the first isolator 170 comprises two fist main bodies 171 and a first vibration isolation cable 172. The first main bodies 171 may be made of aluminum or aluminum alloy, the first vibration isolation cable 172 may be made of stainless steel, and the present invention is not limited thereto. The two first main bodies 171 are opened with many first cable holes 1711. The first vibration isolation cable 172 passes through each of the first cable holes 1711 of the two first main bodies 171 respectively, so as to form a complete vibration isolation structure with the first main bodies 171.

In addition, the server cabinet 100 of the present invention comprises a first connection board 180, which is connected to the first main body 171 facing outward of the first vibration isolator 170 through retention components such as the screws 210, so that the first connection board 180 is disposed opposite to the accommodated frame 160. The first vibration isolator 170 is sandwiched between the accommodated frame 160 and the first connection board 180, and the first connection board 180 is connected to a wall of the outside machine room.

As show in FIGS. 1A, 1B, and 2A to 2C, the server cabinet 100 of the present invention further comprises two second isolators 190, which are disposed at the bottom part 117 of the rack 110, for example in a locked manner by using the screws 210, or are installed on the rack 110 by welding. Those skilled in the art may select any suitable connection manner, and the present invention is not limited thereto. Furthermore, the two second isolators 190 are disposed symmetrically and a certain distance away from each other. The second isolators 190 work together with the first isolators 170 installed at the top part 116 of the rack 110, so as to provide the server cabinet 100 with a most complete protective effect of shock isolation/shock absorption at the same time.

The second isolator 190 comprises two second main bodies 191 and a second vibration isolation cable 192. The second main bodies 191 may be made of aluminum or aluminum alloy, the second shock isolation cable 192 may be made of stainless steel, and the present invention is not limited thereto. The two second main bodies 191 are opened with many second cable holes 1911. The second vibration isolation cable 192 passes through each of the second cable holes 1911 of the two second main bodies 191 respectively, so as to form a complete vibration isolation structure with the second main bodies 191.

Additionally, the server cabinet 100 of the present invention comprises two second connection boards 200, which are connected to the second main bodies 191 of the second isolator 190 respectively through the retention components such as the screws 210, so that the second isolator 190 is sandwiched between the two second connection boards 200. The second isolator 190 is fixedly disposed at the bottom part 117 of the rack 110 through one of the two second connection boards 200, and the other one of the two second connection boards 200 is connected to a wall of the outside machine room.

The isolator of the server cabinet structure of the present invention is installed in the rack and is disposed in the rack, which does not increase the volume of the server cabinet additionally, does not occupy an additional space in the room, and is suitable for being applied to application environment which has narrow spaces. Therefore, the space in the room can be unitized efficiently, and the machine room can be installed with the maximum number of the server racks, thus achieving the highest operation performance.

What is claimed is:

1. A server cabinet structure with a vibration isolation function, comprising:
a rack, having an accommodation room inside;
an accommodated frame, installed on the rack and disposed in the accommodation room; and
a first shock isolator, installed in the accommodated frame and partially exposed out of the rack.

2. The server cabinet structure with the vibration isolation function according to claim 1, further comprising a first connection board connected to the first isolator, wherein the first isolator is sandwiched between the accommodated frame and the first connection board.

3. The server cabinet structure with the vibration isolation function according to claim 1, wherein the first shock isolator comprises two first main bodies and a first vibration isolation cable, each of the first main bodies is opened with at least one first cable hole, and the first vibration isolation cable passes through each of the first cable holes of the two first main bodies respectively, so as to form a vibration isolation structure with the two first main bodies.

4. The server cabinet structure with the vibration isolation function according to claim 3, wherein the two first main bodies are made of aluminum or aluminum alloy, and the first vibration isolation cable is made of stainless steel.

5. The server cabinet structure with the vibration isolation function according to claim 1, further comprising at least one second isolator, wherein the rack has a top part and a bottom part opposite to each other, the accommodated frame is disposed at the top part, the first isolator is installed in the accommodated frame, and the second isolator is installed at the bottom part.

6. The server cabinet structure with the vibration isolation function according to claim 5, wherein the second isolator comprises two second main bodies and a second vibration isolation cable, each of the second main bodies is opened with at least one second cable hole, and the second vibration isolation cable passes through each of the second cable holes of the two second main bodies respectively, so as to form a vibration isolation structure with the two second main bodies.

7. The server cabinet structure with the vibration isolation function according to claim 6, wherein the two second main bodies are made of aluminum or aluminum alloy, and the second vibration isolation cable is made of stainless steel.

8. The server cabinet structure with the vibration isolation function according to claim 5, further comprising two second connection boards, wherein the two second connection boards are connected to two side surfaces opposite to each other of the second isolator respectively, so that the second isolator is sandwiched between the two second connection boards, and the second isolator is installed at the bottom part of the rack through one of the second connection boards.
